(19) United States
(12) Patent Application Publication
(10) Pub. No.: US 2006/0158861 A1
(43) Pub. Date: Jul. 20, 2006

(54) Semiconductor device and display module using same

(76) Inventors: Yasushi Shouji, Fukuyama-shi (JP); Kenji Toyosawa, Fukuyama-shi (JP)

Correspondence Address: HARNESS, DICKEY & PIERCE, P.L.C., P.O. BOX 8910, RESTON, VA, 20195, US

(21) Appl. No.: 11/333,231

(22) Filed: Jan. 18, 2006

(30) Foreign Application Priority Data
Jan. 19, 2005 (JP) 2005-012069

(51) Int. Cl. H05K 1/03

(52) U.S. Cl. 361/750; 174/258; 174/260; 361/783

(57) ABSTRACT

A semiconductor device of a film carrier package type in which wiring patterns formed on a flexible film are connected to electrodes that are used to make contacts with an external circuit and are formed on a semiconductor element or semiconductor elements mounted on the semiconductor device. The flexible film is designed so that the product of Young's modulus and the cube of film thickness of a material of the flexible film is smaller than 4.03×10⁻⁴ (Pa·m³), and that the inverse of the product of Young's modulus and thickness of the flexible film material is smaller than 4.42×10⁻⁶ (Pa⁻¹·m⁻¹). As a result, a semiconductor device and a display module using it are provided in which a substrate formed of a base film can be suitably bent, and in which sprocket holes of the base film will not be broken during transport.

This Nonprovisional application claims priority under 35 U.S.C. § 119(a) on Patent Application No. 012069/2005 filed in Japan on Jan. 19, 2005, the entire contents of which are hereby incorporated by reference.

### FIELD OF THE INVENTION

The present invention relates to a semiconductor device of a tape carrier package type, known as COF (Chip on Film), in which wiring patterns formed on a flexible film are connected to electrodes which are used to make contacts with an external circuit and are formed on a semiconductor element or semiconductor elements mounted on the semiconductor device. The invention also relates to a display module using such a semiconductor device.

### BACKGROUND OF THE INVENTION

In order to drive a liquid crystal panel, a liquid crystal driver provided with a semiconductor element is mounted on the liquid crystal panel by, for example, a COG (Chip on Glass) method, in which a semiconductor chip is directly mounted, or a COF (Chip on Film) or TCP (Tape Carrier Package) method in which a film is used to mount a semiconductor chip.

The COF has a flexible film base structure as exemplified by a semiconductor device 110 illustrated in FIGS. 11(a) and 11(b), in which wiring patterns 102 and 103 are formed on a substrate 101 formed of a flexible film, and a semiconductor element 104 is mounted on the substrate 101.

As illustrated in FIG. 12(a), the semiconductor device 110 is bonded to a liquid crystal display panel 121 and a PW (Printed Wiring) board 130 with an anisotropic conductive adhesive (ACF: Anisotropic Conductive Film) 111, so as to be electrically connected to the liquid crystal display panel 121 and the PW board 130. The result is a display module 100.

The display module 100 is often installed with the PW board 130 bent toward the rear surface of the liquid crystal display panel 121, as shown in FIG. 12(b). Here, if the base film of the tape carrier package were stiff, i.e., if the substrate 101 has a large Young's modulus E, then a large bending reaction force acts on the contacts held by the anisotropic conductive adhesive 111 constituting the fixed end. It is therefore not difficult to imagine that the reliability of contacts can be improved by reducing the bending reaction force, because in this case the amount of force that acts to detach the anisotropic conductive adhesive 111 can be reduced.

In view of this, for example, Patent Document 1(Japanese Laid-Open Patent Publication No. 176370/2003; published on Jun. 24, 2003) proposes using a base film material with a Young's modulus of 4.0 GPa to 6.5 GPa, in order to bend the base film of the tape carrier package more easily. As taught by Patent Document 1, it is undesirable to have a Young's modulus that is too small, in view of suppressing dimensional change caused by tensile force or compressive force that acts on an IC-installed TAB (Tape Automated Bonding) bonded to a printed circuit of electronic device wirings. Further, Patent Document 1 examines Young's modulus from the standpoint of thermal contraction of the base film.

However, the material properties of the base film of the tape carrier package used in the conventional semiconductor device and a display module using the semiconductor device are not sufficient by themselves.

That is to say, when the base film is too flexible, the base film cannot be transported, or sprocket holes 108 shown in FIG. 1 1(b) are broken. It is therefore required to set a suitable Young's modulus and a suitable tape thickness.

### SUMMARY OF THE INVENTION

An object of the present invention is to provide a semiconductor device, and a display module using it, which allow a substrate formed of a base film to be suitably bent, and prevent sprocket holes of the base film from being broken during transport.

In order to achieve the foregoing object, the present invention provides a semiconductor device of a tape carrier package type in which wiring patterns formed on a flexible film are connected to electrodes which are used to make contacts with an external circuit and are formed on a semiconductor element or semiconductor elements mounted on the semiconductor device, wherein the flexible film is designed so that the product of Young's modulus and the cube of film thickness of a material of the flexible film is smaller than 4.03×10⁻⁴ (Pa·m³), and that the inverse of the product of Young's modulus and thickness of the flexible film material is smaller than 4.42×10⁻⁶ (Pa⁻¹·m⁻¹).

According to this configuration, the flexible film is designed so that the product of Young's modulus and the cube of film thickness of a material of the flexible film is smaller than 4.03×10⁻⁴ (Pa·m³), and that the inverse of the product of Young's modulus and thickness of the flexible film material is smaller than 4.42×10⁻⁶ (Pa⁻¹m⁻¹).

The flexible film therefore provides good bending reaction force and is suited for transport. Thus, with the semiconductor device, the substrate formed of the base film can be suitably bent, and the sprocket holes of the base film will not break during transport.

Further, in order to achieve the foregoing object, the present invention provides a display module that uses the foregoing semiconductor device, the display module including: a display panel; and a driving semiconductor element, mounted on the semiconductor device, for supplying an electrical signal to the display panel, wherein the flexible film of the semiconductor device is designed so that the product of Young's modulus and the cube of film thickness of a material of the flexible film is smaller than 4.03×10⁻⁴ (Pa·m³), and that the inverse of the product of Young's modulus and thickness of the flexible film material is smaller than 4.42×10⁻⁶ (Pa⁻¹·m⁻¹).

Thus, with the liquid crystal module provided with the semiconductor device, the substrate formed of the base film can be suitably bent, and the sprocket holes of the base film will not break during transport.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a graph representing a relationship between Young's modulus E and film thickness of a flexible film used in a semiconductor device of the present invention.

FIG. 2(a) is a plan view illustrating a semiconductor device of a COF structure.

FIG. 2(b) is a cross sectional view illustrating the semiconductor device of a COF structure.

FIG. 3(a) is a plan view illustrating a structure of a liquid crystal module using the semiconductor device.

FIG. 3(b) is a cross sectional view taken along line X-X of FIG. 3(a).

FIG. 3(c) is a cross sectional view illustrating the liquid crystal module with a PW board bent toward the rear surface of a liquid crystal display panel.

FIG. 4(a) is a schematic view explaining how flexural rigidity of the flexible film is determined.

FIG. 4(b) is a schematic view explaining how shear stress of the flexible film is determined.

FIG. 5(a) is a plan view representing a transport method of the flexible film.

FIG. 5(b) is a cross sectional view representing the transport method of the flexile film.

FIG. 6 is a plan view representing a bending reaction force testing method of the flexible film.

FIG. 7 is a graph representing a result of a bending reaction force test of the flexible film.

FIG. 8(a) is a cross sectional view representing a shear strength testing method of the flexible film concerning sprocket holes.

FIG. 8(b) is a plan view representing a shear strength testing method of the flexible film concerning sprocket holes.

FIG. 9 is a cross sectional view representing a bending testing method of the flexible film.

FIG. 10 is a graph representing a result of the bending test performed on the flexible film.

FIG. 11(a) is a plan view illustrating a conventional semiconductor device of a COF structure.

FIG. 11(b) is a cross sectional view illustrating the conventional semiconductor device of a COF structure.

FIG. 12(a) is a cross sectional view illustrating a structure of a liquid crystal module using the conventional semiconductor device.

FIG. 12(b) is a cross sectional view illustrating the liquid crystal module with a PW board bent toward the rear surface of the liquid crystal display panel.

### DESCRIPTION OF THE EMBODIMENTS

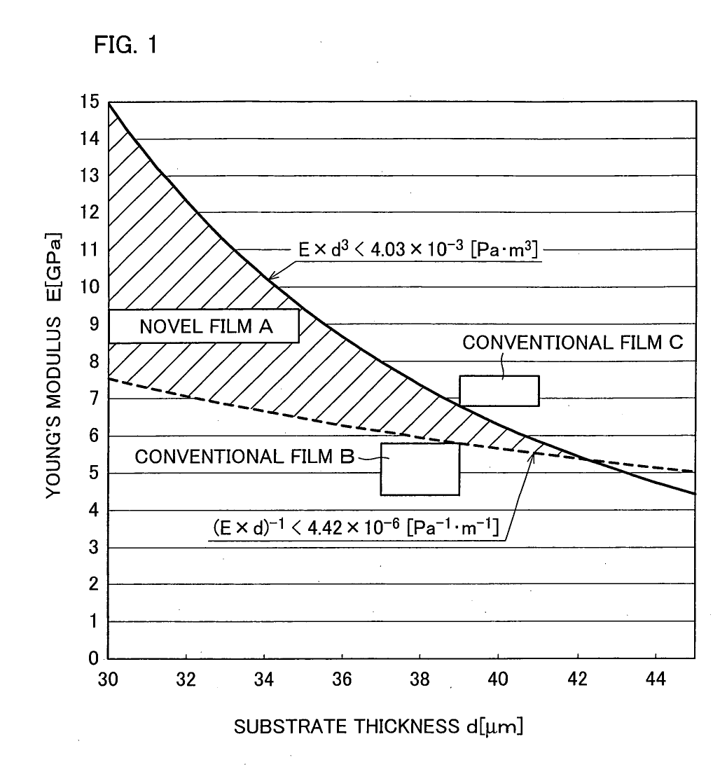

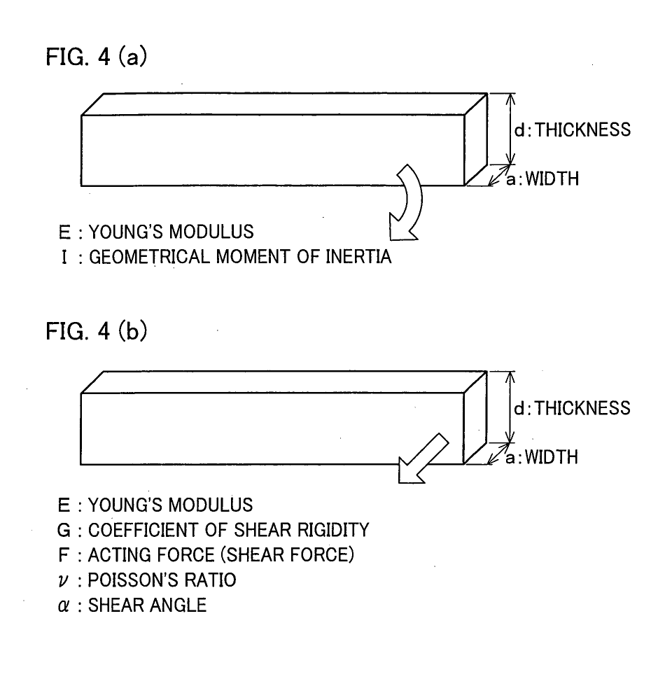

Referring to FIG. 1 through FIG. 10, the following will describe one embodiment of the present invention.

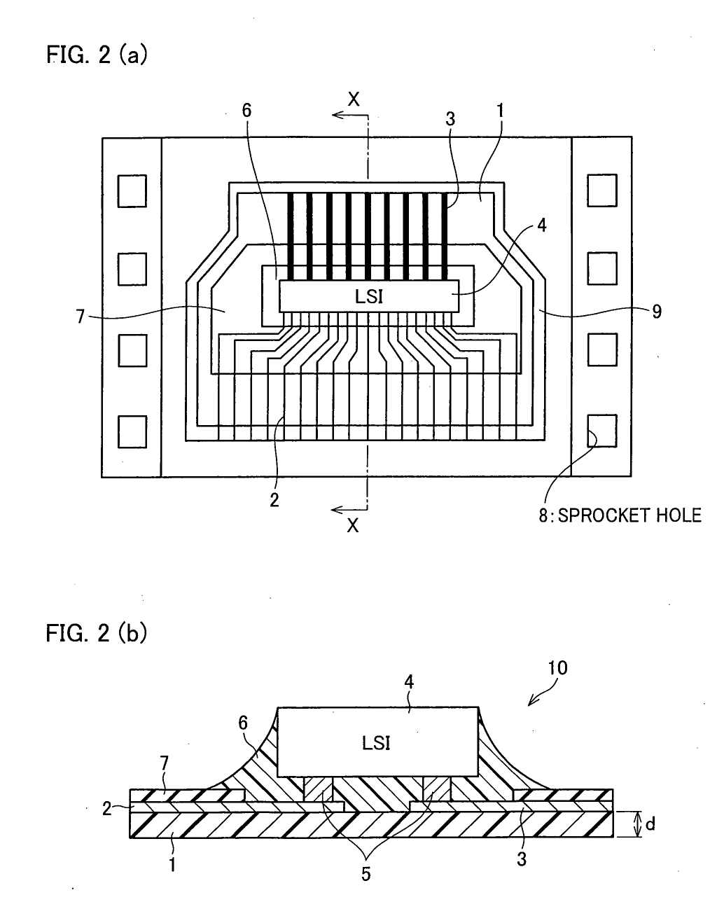

As illustrated in FIGS. 2(a) and 2(b), a semiconductor device 10 of the present embodiment has a COF (chip on film) structure. Specifically, the COF has a flexible film base structure, in which wiring patterns 2 and 3 are formed on a flexible film substrate 1 and a semiconductor element 4 is mounted on the substrate 1. In the COF of the present embodiment, the semiconductor element 4 is directly mounted on the flexible film.

The semiconductor device 10 is for driving a liquid crystal panel 21, which is provided as a display panel and an external circuit, as will be described later. The semiconductor device 10 is structured such that the semiconductor element 4 is connected to the substrate 1 formed of an organic insulating film and on which the wiring patterns 2 and 3 are formed.

The wiring patterns 2 and 3 are made of copper (Cu), for example. However, the material of the wiring patterns 2 and 3 is not just limited to copper. For example, the wiring patterns 2 and 3 may be made of copper (Cu) plated with tin (Sn), or made of gold (Au), or copper (Cu) plated with gold (Au).

The semiconductor element 4 includes bump electrodes 5 made of gold (Au). The bump electrodes 5 are connected to the wiring patterns 2 and 3 to conduct electricity.

The semiconductor device 10 is manufactured such that, for example, a resin underfill 6 is injected into a gap between the semiconductor element 4 and the flexible film and around the semiconductor element 4, after bonding the bump electrodes 5 to the wiring patterns 2 and 3. This improves moisture resistance and mechanical strength of the semiconductor device 10.

As required, a solder resist 7 made of an insulating material is applied to the flexible film, except for external connection terminals, the semiconductor element 4, and areas around the semiconductor element 4. This prevents shorting caused by conductive foreign objects directly adhering to the wiring patterns 2 and 3.

The flexible film has sprocket holes 8, which are transport holes formed on the both sides of the flexible film. The sprocket holes 8 are mated with projections (not shown) to transport the flexible film. During manufacture, a plurality of semiconductor devices 10 are formed in series on a continuous flexible film shown in FIG. 2(a). For use, the semiconductor devices 10 each having the semiconductor chip 4 mounted on the insulating substrate 1 are cut out into individual pieces according to a user-defined shape 9 set for the insulating film.

In the present embodiment, the semiconductor device 10 is mounted on the liquid crystal module 20, which is provided as a display module.

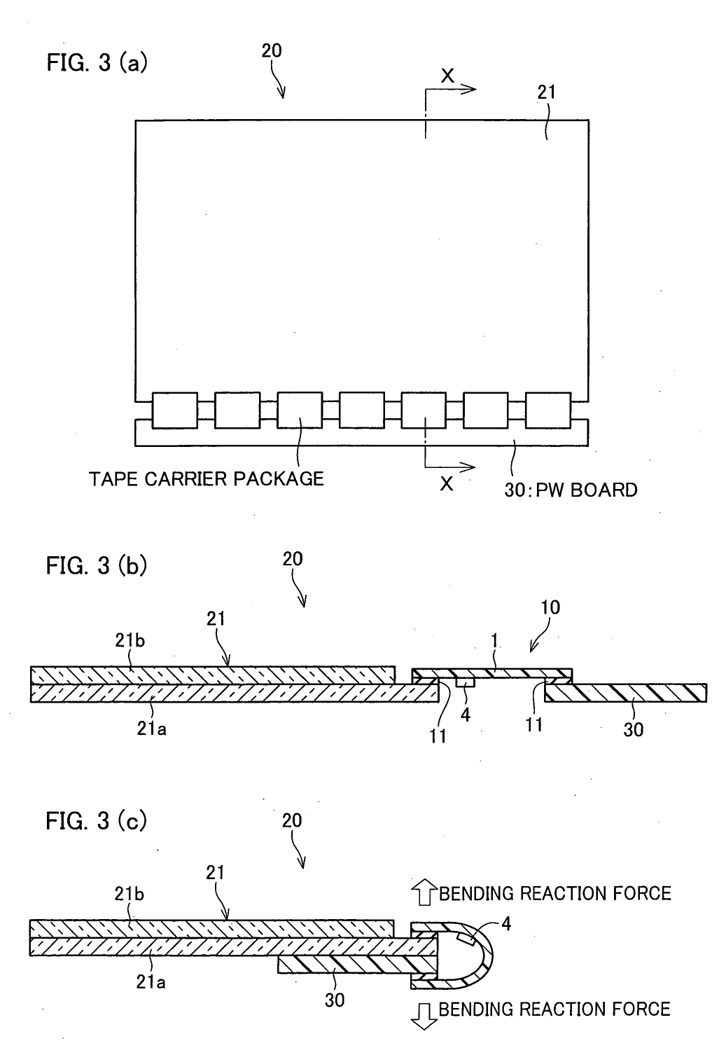

In the liquid crystal module 20 of the present embodiment, as shown in FIGS. 3(a) and 3(b), the semiconductor device 10 is mounted on the liquid crystal display panel 21, which includes a TFT (Thin Film Transistor) substrate 21a and a color filter substrate 21b. On the side of the semiconductor device 10 opposite the liquid crystal display panel 21, a PW (Printed Wiring) board 30 is attached as a circuit board. The semiconductor device 10 is bonded to the liquid crystal display panel 21 and the PW board 30 with an anisotropic conductive adhesive (ACF: Anisotropic Conductive Film) 11, so as to conduct electricity. The anisotropic conductive adhesive 11 is an adhesive film, 15 μm to 45 μm thick, in which conductive particles with a particle size of 3 μm to 15 μm are dispersed. Since the conductive particles are dispersed in the film, the anisotropic conductive film 11 itself is an insulator. However, with the anisotropic conductive adhesive 11 sandwiched between circuit patterns, the upper and lower substrates can be bonded together under applied heat and pressure, while ensuring conduction between upper and lower electrodes and insulation between adjacent electrodes.

As shown in FIG. 3(c), the liquid crystal module 20 is installed with the PW substrate 30 bent toward the rear surface of the liquid crystal display panel 21. Here, if the base film of the tape carrier package were stiff, i.e., if the substrate 1 has a large flexural rigidity, then a large bending reaction force acts on the contacts held by the anisotropic conductive adhesive 11 constituting the fixed end, with the result that the substrate 1 cannot be bent.

It is therefore not difficult to imagine that the reliability of contacts can be improved by reducing the bending reaction force, because in this case the amount of force that acts to detach the anisotropic conductive adhesive 11 can be reduced.

However, if the base flexible film were too flexible, then it will not be possible to carry the flexible film, or the sprocket holes 8 may be broken. It is therefore required to set a suitable Young's modulus and a suitable thickness for the flexible film.

In the present embodiment, a suitable Young's modulus and film thickness of the flexible film (substrate 1 ) were obtained from equations of bending reaction force and equations of shear strain, and from the experiments described in Examples below, taking into consideration bendability, and ease of installation and transport.

Specifically, the following consideration was made for the bending reaction force.

First, when the strain in distance x along the lengthwise direction of the flexible film is y, and the bending moment is M, then the basic equation of strain is given as follows.
d²y/d²x=M/E×I Equation (1)
where E is the Young's modulus of the flexible film, and I is the geometrical moment of inertia. It follows from Equation 1 that
M=(E×I)×(d²y/d²x)
∝ E×I Equation (2).

It can be seen from Equation (2) that the geometrical moment of inertia M is proportional to E×I, which represents flexural rigidity. That is, the bending reaction force is proportional to flexural rigidity E×I.

Here, when the width and thickness of the flexible film are a and d, respectively, the flexural rigidity E×I is given by the following Equation.
Flexural rigidity E×I=E×(a×d³)/12
∝ E×d³ Equation ( 3)
Thus, per unit width of the flexible film, the flexural rigidity of the material is proportional to the product of Young's modulus E and the cube of thickness d.

Hence, the bending reaction force of the flexible film can be determined based on the product of Young's modulus and the cube of thickness d. In order to reduce the bending reaction force below a certain value, a constant k1 is set as given by Equation (4) below.
E×d³≦k1 Equation (4)

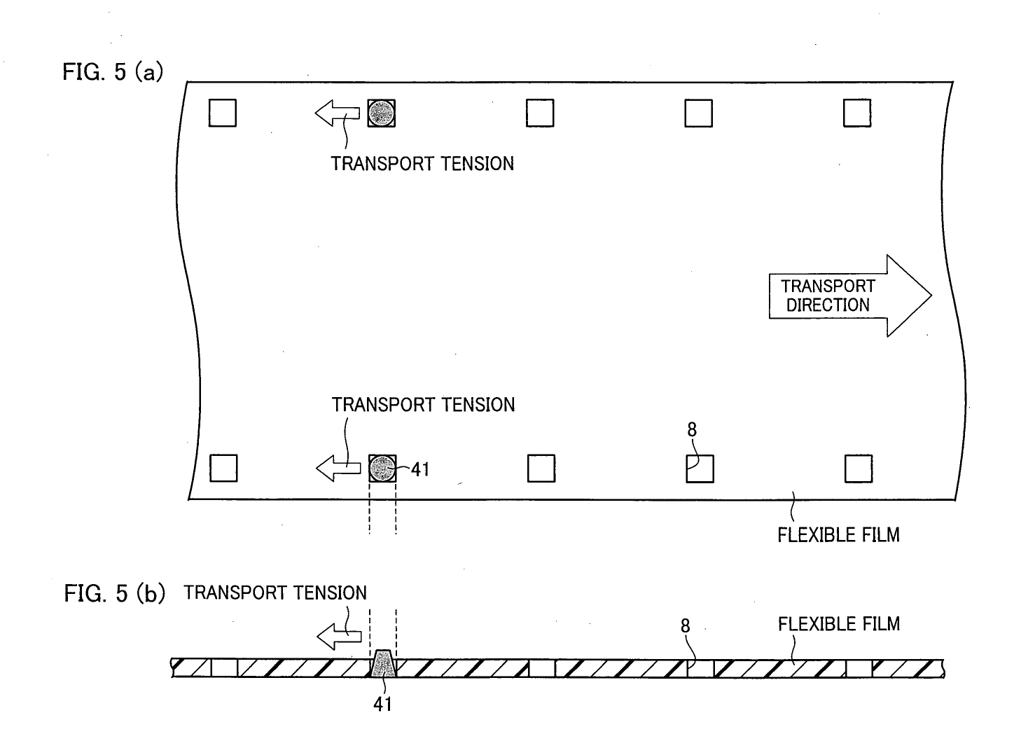

Referring to FIGS. 5(a) and 5(b), description is made below as to ease of transport. The tape carrier or tape carrier package is transported reel to reel. During stamping or transport, shear stress acts on the sprocket hole 8 in the reverse direction of the transport direction, with a registration guide pin 41 or the like serving as a fulcrum. Here, the smaller the strain caused by the shear stress, the less the extent of deformation of the sprocket hole 8. Thus, by reducing the strain, the registration accuracy of the transport can be improved.

The shear stress can be given by the following equations.
Shear stress=F/S=F/(a×d) Equation (5)
Shear stress=G×tan α≈G×α Equation (6)
G=E/2(1+v) Equation (7)
where a is the width of the flexible film, d is the thickness, E is the Young's modulus, G is the coefficient of shear rigidity, v is the Poisson's ratio, F is the shear force, S is the area acted upon by the shear force, and a is the shear angle.

Here, since G=E/2 (1+v) as given by Equation (7), the coefficient G of shear rigidity is proportional to Young's modulus E, provided that the Poisson's ratio v is constant. Thus, Equation (6) can be expressed as
Shear stress≈G×α ∝ E×α Equation (8).
Since Equation (5)=Equation (8),
shear angle α ∝ F/((a×d)×E)
∝ 1/(E×d) Equation (9)

Thus, given a constant shear force per unit width, the shear angle α of the material is inversely proportional to the product of Young's modulus and thickness d.

Therefore, the inverse of the product of Young's modulus E and thickness d of the flexible film (E×d)⁻¹ can be used to determine conditions necessary for the transport of the flexible film. In order to prevent shear destruction of the sprocket holes 8 in the flexible film, a constant k2 is set as given by the following Equation (10).
(E×d)⁻¹≦k2 Equation (10)

In order to find constants k1 and k2, the present embodiment examined conventional defect films B and C by the experiments described in Examples below. After determining constants k1 and k2, the effectiveness of a novel film A satisfying the conditions of both bending reaction force and ease of transport was confirmed.

The conventional films B and C had Young's modulus E and thickness d as shown in Table 1. The values of Young's modulus E and thickness d shown in Table 1 are minimum and maximum values obtained by arbitrarily sampling each type of film from 30 lots. The values of E×d³ and (E×d)⁻¹ were calculated from these values of Young's modulus E and thickness d.

It was found by experiment, as will be described in Examples, that the bending reaction force of the conventional film C was too large to provide good bendability or ease of installation, as shown in Table 2. In conventional film C, there was no breakage of the sprocket holes 8 during transport. Conventional film B had a very small Young's modulus E and did not exert large bending reaction force. However, the sprocket holes 8 were broken during the punching step performed before installation, making it impossible to transport the flexible film.

It is therefore preferable that the flexible film have a smaller bending reaction force than conventional film C and a greater sprocket hole 8 strength than conventional film B. That is, it is preferable that the inverse of the product of Young's modulus E and thickness d of the flexible film material (E×d)⁻¹ be smaller than that of conventional film B.

In numerical representations, as can be seen from Table 1, it is preferable, in consideration of bending reaction force, that the product of Young's modulus E and the cube of thickness d of the flexible film material (E×d³) be smaller than the minimum value 4.03×10⁻⁴ (Pa·m³) of conventional film C. As to ease of transport, it is preferable that the inverse of the product of Young's modulus E and thickness d of the flexible film material (E×d)⁻¹ be smaller than 4.42×10⁻⁶ (Pa⁻¹·m⁻¹) of conventional film B. In graphical representations, these ranges are shown by the hatched region in FIG. 1.

Generally, the adhesion to other materials tends to be reduced when the Young's modulus E of the flexible film material is large. It is therefore preferable that, even in the hatched region in FIG. 1, that a flexible film material with a small Young's modulus be selected. Examples of materials to which the flexible film material needs to have good adhesion include, but are not limited to, the wiring patterns 2 and 3, the underfill 6, the solder resist 7, and the anisotropic conductive adhesive 11.

Novel film A of properties within these ranges was studied. As a result, a suitable thickness of the flexible film was found to be 30 μm to 35 μm, as will be described in Examples.

In novel film A, ease of transport suffered when the thickness of the flexible film was 25 μm, as shown in Table 3 in Examples.

TABLE 1
Physical Properties and Results of Calculations for Conventional Materials and Novel Material

| | FLEXIBLE FILM | | E | d | Ed³ | | 1/(E · d) | | FINAL |
|---|---|---|---|---|---|---|---|---|---|
| | MATERIAL | | GPa | μm | Pa · m³ | JUDGMENT | (Pa · m)⁻¹ | JEDGMENT | JUDGMENT |
| COM. | CONVENTIONAL | MIN | 4.4 | 37 | 2.23E−04 | ∘ | 6.14E−06 | x | x |
| EX. | FILM B | MAX | 5.8 | 39 | 3.44E−04 | ∘ | 4.22E−06 | x | |
| | CONVENTIONAL | MIN | 6.8 | 39 | 4.03E−04 | x | 3.77E−06 | ∘ | x |
| | FILM C | MAX | 7.6 | 41 | 5.24E−04 | x | 3.21E−06 | ∘ | |
| EX. | NOVEL FILM A | MIN | 8.5 | 30 | 2.30E−04 | ∘ | 3.92E−06 | ∘ | ∘ |
| | | MAX | 9.3 | 35 | 3.99E−04 | ∘ | 2.69E−06 | ∘ | |

As described above, the semiconductor device 10 of the present embodiment has a flexible film in which the product of Young's modulus and the cube of thickness of the flexible film material is smaller than 4.03×10⁻⁴ (Pa·m³), and in which the inverse of the product of Young's modulus and thickness of the flexible film material is smaller than 4.42×10⁻⁶ (Pa⁻¹·m⁻¹).

The flexible film therefore provides good bending reaction force and is suited for transport. Thus, with the semiconductor device 10, the substrate 1 formed of the base film can be suitably bent, and the sprocket holes 8 of the base film will not break during transport.

In the semiconductor device 10, it is preferable that the flexible film be made of a polymer material. The polymer material used for the flexible film of the semiconductor device 10 is preferably polyimide, or acrylic or aramid resin.

The semiconductor device 10 of a COF structure is generally formed of a flexible film made of a polymer material such as polyimide, acrylic resin, or aramid resin. Thus, with the semiconductor device 10, the substrate 1 formed of the base film can be suitably bent, and the sprocket holes 8 of the base film will not break during transport.

In the semiconductor device 10, it is preferable that the thickness of the flexible film is in a range of 30 μm to 35 μm, inclusive.

This ensures that the substrate 1 formed of the base film can be suitably bent, and that the sprocket holes 8 of the base film will not break during transport.

The liquid crystal module 20 of the present embodiment includes the liquid crystal panel 21, and the semiconductor element 4, mounted on the semiconductor device 10, for driving the liquid crystal panel 21 by supplying electrical signals, wherein the flexible film of the semiconductor device 10 is set so that the product of Young's modulus and the cube of thickness of the flexible film material is smaller than 4.03×10⁻⁴ (Pa·m³), and that the inverse of the product of Young's modulus and thickness of the flexible film material is smaller than 4.42×10⁻⁶ (Pa⁻¹·m⁻¹).

Thus, with the liquid crystal module 20 provided with the semiconductor device 10, the substrate 1 formed of the base film can be suitably bent, and the sprocket holes 8 of the base film will not break during transport.

In the liquid crystal module 20, it is preferable that the semiconductor device 10 be connected to the PW board 30 for supplying power to the semiconductor element 4.

This enables the PW board 30 to supply power to the semiconductor element 4 mounted on the semiconductor device 10.

Further, in the liquid crystal module 20, it is preferable that the liquid crystal panel 21 is a display panel.

Thus, with the liquid crystal module 20 provided with the semiconductor device 10, the substrate 1 formed of the base film can be suitably bent, and the sprocket holes 8 of the base film will not break during transport.

### EXAMPLES

The following will describes the present invention in more detail by way of Examples. Note that, novel film A, conventional film B, and conventional film C used in Examples below are all made of polyimide.

[Bending Reaction Force]

COF is used where the glass display panel is connected to the semiconductor element and circuit board. When used as a module, the circuit board is often bent toward the rear surface of the display panel. Thus, for desirable flexibility and operability, the COF needs to have good bendability when used as a module.

In view of this, a comparative test was conducted to examine the reaction force exerted when bending the flexible film.

Novel film A, conventional film B, and conventional film C were used as sample flexible films. Novel film A had a young's modulus E=9.3 GPa, and three different thicknesses d=25 μm, 30 μm, and 35 μm. Conventional film B had a Young's modulus E=4.8 GPa, and a film thickness d=38 μm. Conventional film C had a Young's modulus E=6.8 GPa, and a film thickness d=40 μm.

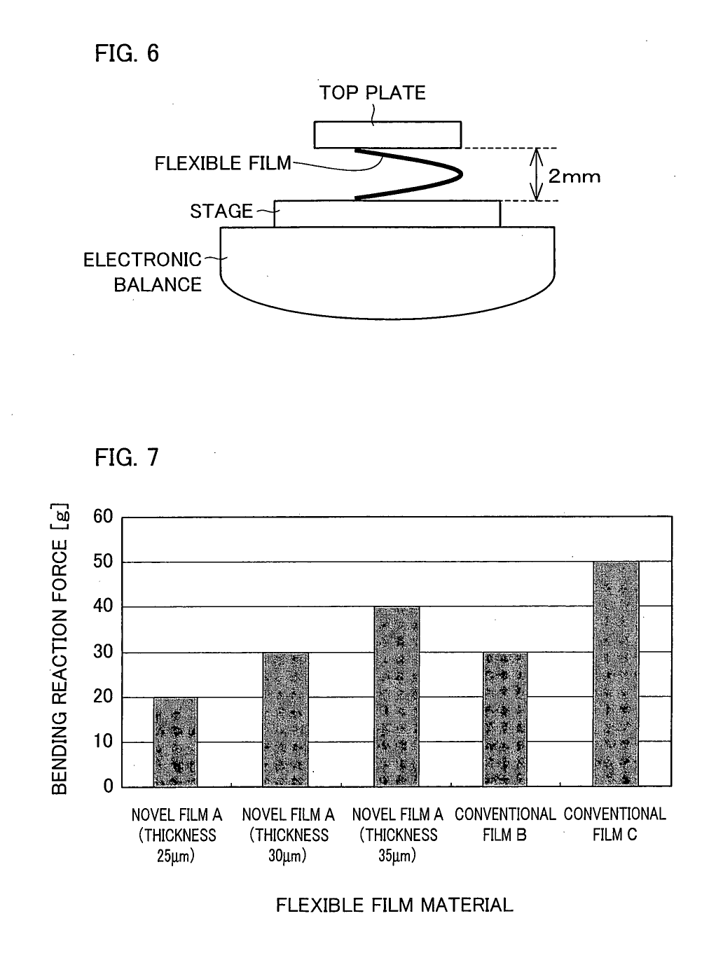

In the test, a flexible film of each sample (novel film A, conventional film B, conventional film C) was cut into a predetermined size (10 mm×20 mm). Then, as illustrated in FIG. 6, the film was bent with its cupper wiring patterns facing inward, and was set in a 2 mm gap between a top plate anchored above an electronic balance, and a stage placed on the electronic balance. After one minute, readings on the electronic balance were confirmed.

The results are shown in Table 2 and FIG. 7. As can be seen from Table 2 and FIG. 7, novel film A and conventional film B had a bending reaction force below 40 g, and their bendability was judged to be good. Conventional film C had a bending reaction force of 50 g, and its bendability was judged to be bad.

TABLE 2
Results of Bending Reaction Force Measurement

| | FLEXIBLE FILM MATERIAL | | | | |
|---|---|---|---|---|---|
| | NOVEL | | | CONVENTIONAL | CONVENTIONAL |
| SAMPLE | FILM A | | | FILM B | FILM C |
| YOUNG'S | 9.4 | | | 4.8 | 6.8 |
| MODULUS | | | | | |
| (GPa) | | | | | |
| THICKNESS d | 25 | 30 | 35 | 38 | 40 |
| (μm) | | | | | |
| BENDING | 20 | 30 | 40 | 30 | 50 |
| REACTION | | | | | |
| FORCE | | | | | |
| (g) | | | | | |
| JUDGMENT | ∘ | ∘ | ∘ | ∘ | x |

[Ease of Transport (Strength of Sprocket Holes)]

Ease of transport (strength of sprocket holes) was examined as follows.

In transporting the flexible film, a certain tension needs to be applied to eliminate slack and achieve flatness. Further, in the stamping step in which the flexible film is stamped out into individual pieces of semiconductor elements 4 to be mounted on the liquid crystal display panel 21 formed of a glass substrate, a large stress is exerted in portions fixed with the registration guide pins of the mold. Thus, in order to prevent breakage of the flexible film and maintain good registration accuracy, it is necessary to provide sufficient strength and dimensional stability for the sprocket holes 8, which is exerted upon by such a force.

In order to examine shear strength of the sprocket holes 8, a comparative test was conducted in the manner described below.

Novel film A and conventional film B were used as sample flexible films. Novel film A had a young's modulus E=9.3 GPa, and three different thicknesses d=25 μm, 30 μm, and 35 μm. Conventional film B had a Young's modulus E=4.8 GPa, and a film thickness d=38 μm.

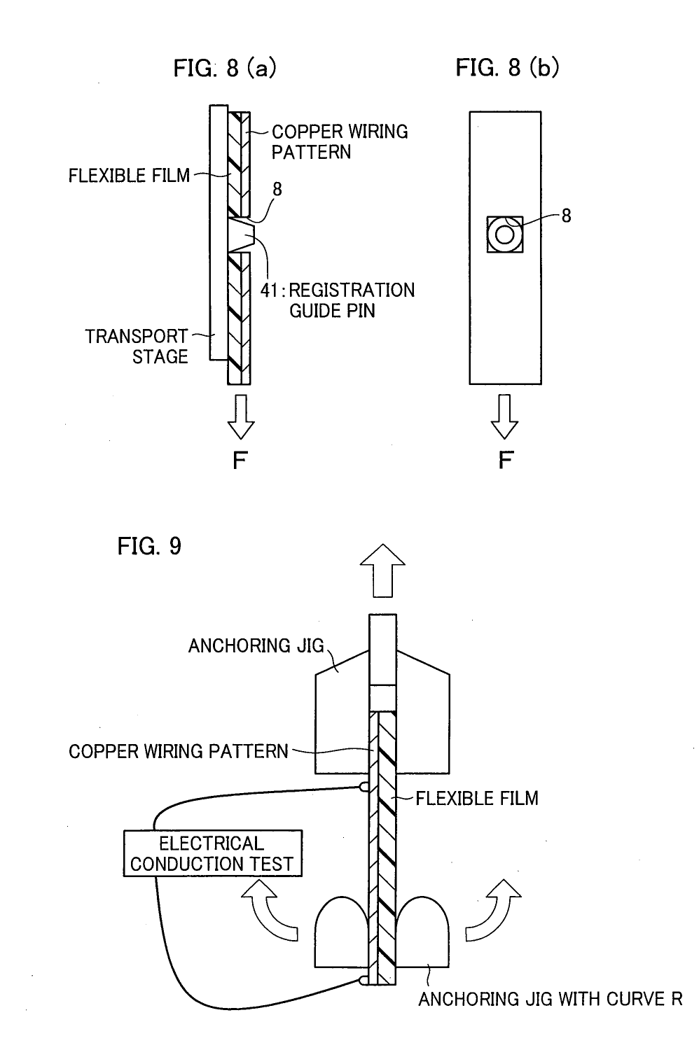

In the experiment, as illustrated in FIGS. 8(a) and 8(b), the flexible film was cut out to form the sprocket holes 8 (4 mm×4 mm). The sprocket holes 8 were then fixed on the registration guide pins 41, and a load was put in a direction of transport. The flexible film was released after one minute, and the sprocket holes 8 were observed under a metaloscope. The load was applied by a counterweight method, and the procedure was repeated by increasing the weight by 100 g each time.

The amount of weight needed to deform or break the sprocket holes 8 was compared between novel film A and conventional film B.

The results are shown in Table 3. In conventional film B, deformation occurred at 300 g, and the sprocket holes 8 were broken under 400 g. In novel film A of 25 μm thick, deformation occurred at 300 g as in conventional film B, but the sprocket holes 8 were not broken until 500 g. The amount of load needed to deform or break the novel film A increased as the film thickness increased. Specifically, at a film thickness of 30 μm, deformation occurred at 400 g, and the sprocket holes 8 were broken under 500 g. At a film thickness of 35 μm, deformation occurred at 500 g, and the sprocket holes 8 were broken under 700 g.

The test therefore showed that, in order to provide a greater sprocket hole strength than conventional film B, a film thickness of 30 μm or greater is needed for novel film A.

TABLE 3
Results of Sprocket Hole Strength Comparative Test

| | FLEXIBLE FILM MATERIAL | | | |
|---|---|---|---|---|
| | | NOVEL FILM A | | |
| | CONVENTIONAL FILM B | (THICKNESS | (THICKNESS | (THICKNESS |
| LOAD | (THICKNESS 38 μm) | 25 μm) | 30 μm) | 35 μm) |
| 100 g | ∘ | ∘ | ∘ | ∘ |
| 200 g | ∘ | ∘ | ∘ | ∘ |
| 300 g | Δ | Δ | ∘ | ∘ |
| 400 g | x | Δ | Δ | ∘ |
| 500 g | | x | x | Δ |
| 600 g | | | | Δ |

∘: NO DEFORMATION OR DAMAGE
Δ: DEFORMATION
x: DAMAGE

[Bending Durability Test]

A general feature of the flexible film is that it can be bent at any portions, and the flexible film is most always installed by being bent. Further, in the event where defect is found in a lighting test of the display module, there are cases, depending on the type of defect, where the COF is once detached from the glass panel and reconnected to it. In detaching the COF, a bending stress may act on the detached portion, and this may lead to wire breakage. Therefore, the flexible film requires sufficient bendability.

In order to examine bending durability of the flexible film, a comparative test was conducted in the manner described below.

Novel film A, conventional film B, and conventional film C were used as sample flexible films. Novel film A had a young's modulus E=9.3 GPa, and three different thicknesses d=25 μm, 30 μm, and 35 μm. Conventional film B had a Young's modulus E=4.8 GPa, and a film thickness d=38 μm. Conventional film C had a Young's modulus E=6.8 GPa, and a film thickness d=40 μm.

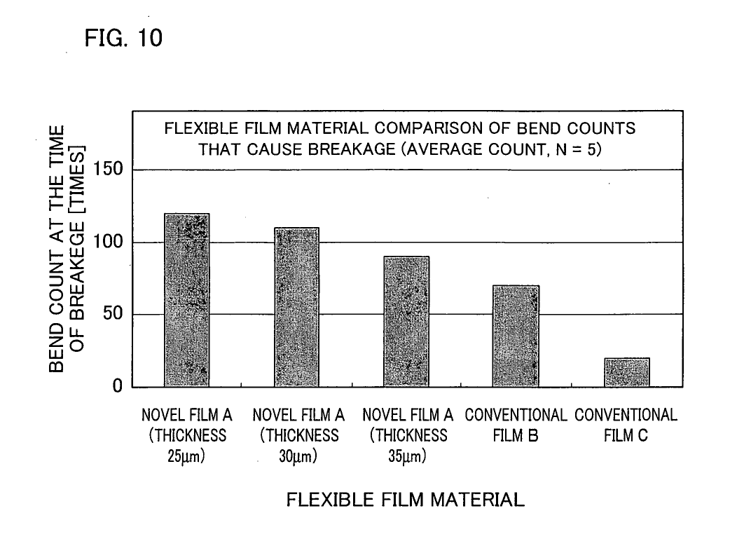

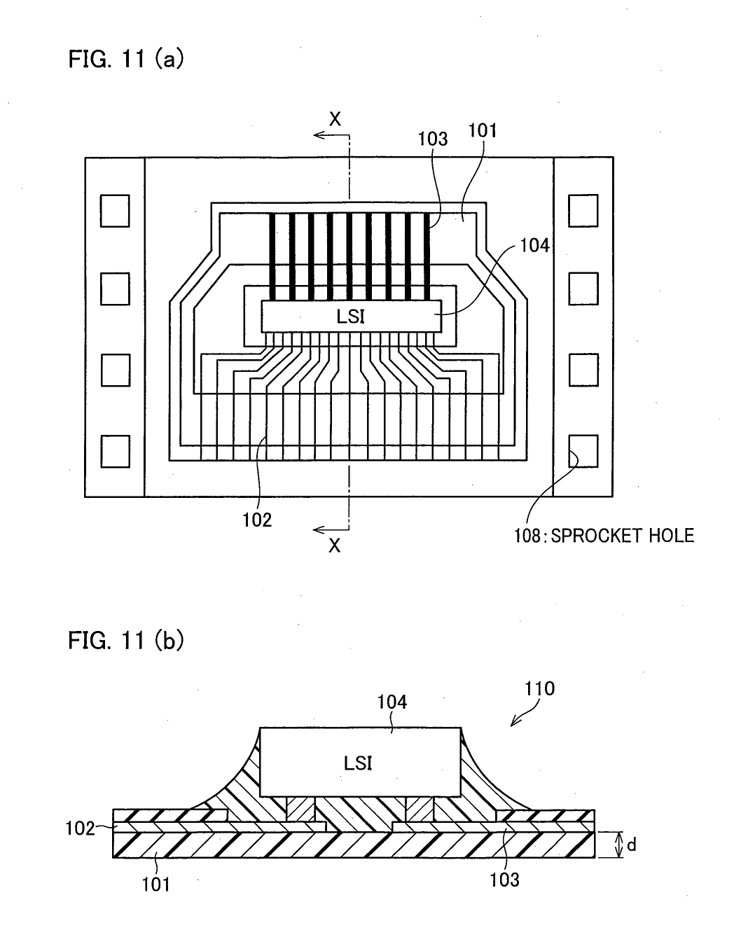

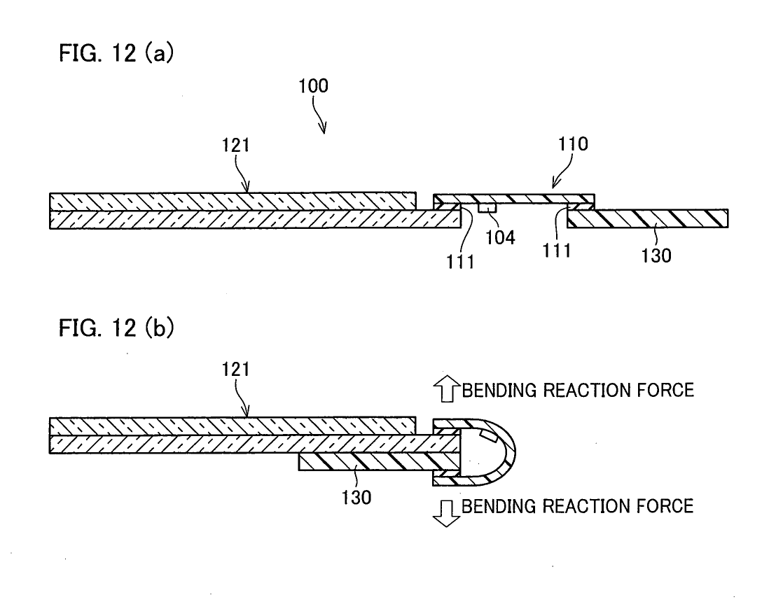

The test was performed according to the following method. First, as illustrated in FIG. 9, a flexible film with copper wiring patterns was anchored with an anchoring jig. With a certain amount of load put on the anchoring jig, the other end of the flexible film was anchored with another anchoring jig with curve R. The flexible film was bent by rotating the anchoring jig with curve R within a ±90° range. In bending the flexible film, electrical conductivity of the copper wiring patterns was also checked by counting the number of times the flexible film was bent until the copper wiring patterns were broken. In this manner, the bend count that caused breakage of the copper wiring patterns was compared between different samples.

The results are shown in Table 4. As can be seen from Table 4, bendability of the novel film A improved with decrease in film thickness.

TABLE 4
RESULTS OF BENDING DURABILITY TEST

| | FLEXIBLE FILM MATERIAL | | | | |
|---|---|---|---|---|---|
| | | | | CONVENTIONAL | CONVENTIONAL |
| SAMPLE | NOVEL FILM A | | | FILM B | FILM C |
| THICKNESS d | 25 | 30 | 35 | 38 | 40 |
| (μm) | | | | | |
| BEND COUNT AT THE | 120 | 110 | 90 | 70 | 20 |
| TIME OF BREKAGE | | | | | |
| (TIMES) | | | | | |
| [AVERAGE COUNT, N = 5] | | | | | |

The present invention is applicable to a semiconductor device of a tape carrier package type, known as COF, in which wiring patterns formed on a flexible film are connected to electrodes which are used to make contacts with an external circuit and are formed on a semiconductor element or semiconductor elements mounted on the semiconductor device. The invention is also applicable to a display module using such a semiconductor device.

Examples of a display module include: a liquid crystal display module of, for example, an active-matrix type; an electrophoretic display, twist-ball display, a reflective display using a micro prism film, a digital mirror display, and similar types of displays employing a light modulation device; an organic EL light emitting element, inorganic EL light emitting element, a LED (Light Emitting Diode), and similar types of displays employing a light emitting element capable of varying luminance; a field emission display (FED); and a plasma display.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A semiconductor device of a tape carrier package type in which wiring patterns formed on a flexible film are connected to electrodes which are used to make contacts with an external circuit and are formed on a semiconductor element or semiconductor elements mounted on the semiconductor device,
wherein the flexible film is designed so that the product of Young's modulus and the cube of film thickness of a material of the flexible film is smaller than 4.03×10⁻⁴ (Pa·m³), and that the inverse of the product of Young's modulus and thickness of the flexible film material is smaller than 4.42×10⁻⁶ (Pa⁻¹·m⁻¹).

2. The semiconductor device as set forth in claim 1, wherein the flexible film is made of a polymer material.

3. The semiconductor device as set forth in claim 2, wherein the polymer material of the flexible film is one of polyimide, acrylic resin, and aramid resin.

4. The semiconductor device as set forth in claim 1, wherein the film thickness of the flexible film is in a range of from 30 μm to 35 μm, inclusive.

5. A display module that uses a semiconductor device of a tape carrier package type in which wiring patterns formed on a flexible film are connected to electrodes which are used to make contacts with an external circuit and are formed on a semiconductor element or semiconductor elements mounted on the semiconductor device,
said display module comprising:
a display panel; and
a driving semiconductor element, mounted on the semiconductor device, for supplying an electrical signal to the display panel,
wherein the flexible film is designed so that the product of Young's modulus and the cube of film thickness of a material of the flexible film is smaller than 4.03×10⁻⁴ (Pa·m³), and that the inverse of the product of Young's modulus and thickness of the flexible film material is smaller than 4.42×10⁻⁶ (Pa⁻¹·m⁻¹).

6. The display module as set forth in claim 5, wherein the semiconductor device is connected to a circuit board that supplies power to the semiconductor element mounted on the semiconductor device.

7. The display module as set forth in claim 5, wherein the display panel comprises a liquid crystal display panel.
